(19) United States
(12) Patent Application Publication
(10) Pub. No.: US 2012/0202316 A1
(43) Pub. Date: Aug. 9, 2012

(54) PLASMA TREATMENT OF TCO LAYERS FOR SILICON THIN FILM PHOTOVOLTAIC DEVICES

(75) Inventors: KHALED AHMED, Anaheim, CA (US); Klaus Schuegraf, San Jose, CA (US)

(73) Assignee: APPLIED MATERIALS, INC., Santa Clara, CA (US)

(21) Appl. No.: 13/360,423

(22) Filed: Jan. 27, 2012

Related U.S. Application Data
(60) Provisional application No. 61/439,162, filed on Feb. 3, 2011.

(51) Int. Cl. H01L 31/18

(52) U.S. Cl. 438/87; 257/E31.061

(57) ABSTRACT

Embodiments of the invention generally provide methods for forming a silicon-based photovoltaic (PV) device containing a transparent conductive oxide (TCO) layer that is exposed to a very high frequency (VHF) plasma. In one embodiment, a method includes depositing a TCO layer on an underlying surface, such as a transparent substrate, and exposing the TCO layer to a VHF plasma to form a treated surface on the TCO layer during a plasma treatment process. The VHF plasma is generated by ionizing a process gas containing hydrogen (H₂) and nitrous oxide at an excitation frequency within a range from about 30 MHz to about 300 MHz. The method further includes forming a p-i-n junction over the TCO layer, wherein the p-i-n junction contains a p-type Si-based layer disposed on the treated surface of the TCO layer. In some examples, the TCO layer contains zinc oxide and the p-i-n junction contains amorphous silicon.

### CROSS-REFERENCE TO RELATED APPLICATION

This application claims benefit of U.S. Ser. No. 61/439,162 (APPM/015514L), filed Feb. 3, 2011, which is herein incorporated by reference in its entirety.

### BACKGROUND OF THE INVENTION

1. Field of the Invention

Embodiments of the invention generally relate to methods for forming photovoltaic devices, and more particularly to plasma treatment of the transparent conductive oxide (TCO) layers utilized within thin film photovoltaic devices.

2. Description of the Related Art

Photovoltaic (PV) or solar cells are devices which convert sunlight into direct current electrical power. Each individual PV cell generates a specific amount of electrical energy. Therefore, multiple PV cells may be bundled or tiled into a solar module that is scaled to deliver a desired amount of electrical energy.

PV or solar cells typically have one or more p-i-n junctions. When the p-i-n junction of the PV cell is exposed to photons, such as from sunlight, the light is directly converted to electricity through the PV effect. Each p-i-n junction contains three distinct regions within a semiconductor material, where one side is p-doped and denoted as the p-type region, the opposite side is n-doped and denoted as the n-type region, and therebetween, separating the p-type and n-type regions is the intrinsic layer which is denoted as the i-type region.

Silicon, germanium, and Group III/V materials are utilized as semiconductor materials contained within various regions of the p-i-n junction. Several types or phases of silicon materials include amorphous silicon (α-Si), microcrystalline silicon (μc-Si), polycrystalline silicon (poly-Si), and doped derivatives thereof. Some p-i-n junctions contain the silicon material in only one phase while other p-i-n junctions contain silicon materials in a mixture of phases throughout various regions of the p-i-n junction.

A transparent conductive film, sometimes referred to as a transparent conductive oxide (TCO) is utilized as an electrode or a contact, such as a top surface electrode of a PV solar cell. Furthermore, a TCO layer may also be disposed as an electrode or a contact between a substrate and a photoelectric conversion unit or between two photoelectric conversion units. The TCO generally has high optical transmittance in the visible or higher wavelength region to facilitate transmitting sunlight into the solar cells without adversely absorbing or reflecting light energy. Additionally, low contact resistance and high electrical conductivity of the TCO are desired properties in order to provide high photoelectric conversion efficiency and electricity collection. A certain degree of texture or surface roughness of the TCO is also desired to assist sunlight trapping in the films by promoting light scattering. Impurities or contaminants within or on the TCO often result in overly high contact resistance at the interface of the TCO and adjacent layers, thereby reducing carrier mobility within the PV cell. Furthermore, insufficient transparency of the TCO adversely reflects light back into the surrounding environment, resulting in a diminished amount of light entering the PV cells and a reduction in the photoelectric conversion efficiency of the PV cell.

Therefore, there is a need for a method for forming a photovoltaic cell with a minimal barrier height at the interface between the TCO and the p-i-n junction by reducing defects on the TCO in order to maximize the photoelectric conversion efficiency and to reduce production costs.

### SUMMARY OF THE INVENTION

Embodiments of the invention generally provide methods for forming a silicon-based photovoltaic (PV) device containing a transparent conductive oxide (TCO) layer which is exposed to a very high frequency (VHF) plasma during a plasma treatment process. In one embodiment, a method for forming a silicon-based PV device is provided which includes depositing or otherwise forming the TCO layer on a transparent substrate, exposing the TCO layer to a VHF plasma to form a treated surface on the TCO layer during a plasma treatment process, wherein the VHF plasma is generated by ionizing (e.g., igniting) a process gas containing hydrogen gas (H₂) and nitrous oxide at an excitation frequency within a range from about 30 MHz to about 300 MHz. The method further includes forming a p-i-n junction over the TCO layer, wherein the p-i-n junction contains a p-type Si-based layer disposed on the treated surface of the TCO layer. The TCO layer contains a metal oxide such as zinc oxide, indium oxide, tin oxide, indium tin oxide, cadmium oxide, cadmium stannate, aluminum oxide, doped variants thereof, derivatives thereof, or combinations thereof. The p-i-n junction further contains an intrinsic Si-based layer disposed over the p-type Si-based layer and an n-type Si-based layer disposed over the intrinsic Si-based layer. In some examples, the TCO layer contains zinc oxide and each of the p-type Si-based layer, the intrinsic Si-based layer, and the n-type Si-based layer independently contains amorphous silicon.

In another embodiment, a method for forming a silicon-based PV device is provided which includes depositing a TCO layer containing zinc oxide on an underlying surface, and exposing the TCO layer to a VHF plasma to form a treated surface on the TCO layer during a plasma treatment process. The VHF plasma is generated by ionizing a process gas containing hydrogen gas and nitrous oxide at an excitation frequency within a range from about 30 MHz to about 300 MHz. The method further includes forming a p-type Si-based layer over the treated surface of the TCO layer, forming an intrinsic Si-based layer over the p-type Si-based layer, and forming an n-type Si-based layer over the intrinsic Si-based layer. The TCO layer containing zinc oxide may be formed by a physical vapor deposition (PVD) process, an electroless chemical deposition/plating process, or a plasma enhanced chemical vapor deposition (PE-CVD) process.

In another embodiment, a method for forming a silicon-based, tandem junction PV device is provided which includes depositing a first TCO layer on a transparent substrate (e.g., PV cell window), exposing the first TCO layer to a VHF plasma during a first plasma treatment process, wherein the VHF plasma is generated by ionizing (e.g., igniting) a process gas containing hydrogen gas and nitrous oxide at an excitation frequency within a range from about 30 MHz to about 300 MHz. The method further includes forming a first p-i-n junction over the first TCO layer, wherein the first p-i-n junction contains a first p-type Si-based layer disposed on the first TCO layer, forming a second TCO layer containing zinc oxide on a first n-type Si-based layer within the first p-i-n junction, and exposing the second TCO layer to the VHF plasma during a second plasma treatment process. Thereafter, the method includes forming a second p-i-n junction over the second TCO layer, wherein the second p-i-n junction contains a second p-type Si-based layer disposed on the second TCO layer.

In some examples, the VHF plasma is generated at the excitation frequency within a range from about 30 MHz to about 300 MHz, more narrowly within a range from about 40 MHz to about 150 MHz, and more narrowly within a range from about 50 MHz to about 100 MHz. The power level of the VHF plasma is generally maintained within a range from about 0.01 W/cm² to about 10.0 W/cm², and more narrowly within a range from about 0.1 W/cm² to about 5.0 W/cm². The TCO layer is usually exposed to the VHF plasma for a time period within a range from about 2 seconds to about 30 seconds. In some examples, the process gas contains hydrogen gas and nitrous oxide at a H₂/N₂O concentration ratio within a range from about 1:1 to about 10:1, for example, about 2:1.

The methods described herein may be used to form silicon-based PV devices, such as a single junction PV cell that contain amorphous silicon or a tandem junction PV cell that contains amorphous silicon in the first PV cell and microcrystalline silicon in the second PV cell. In some examples, the underlying surface is a transparent substrate (e.g., a PV cell window) which contains a transparent material, such as glass, quartz, crystalline, silicon, silicon oxide, silicon dioxide, and polymeric or oligomeric (e.g., plastic), derivatives thereof, or other materials. For example, the transparent substrate may be a glass pane or a glass sheet. In other examples, the underlying surface is an underlying layer containing an n-type material or an n-type Si-based layer contained within a p-i-n junction, such as within a tandem junction PV cell. For example, the n-type Si-based layer may contain an n-doped amorphous silicon material.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts an exemplary cross-sectional view of a single junction silicon-based, thin film PV cell, as described by some embodiments herein; and

FIG. 2 depicts an exemplary cross-sectional view of a tandem junction silicon-based, thin film PV cell, as described by other embodiments herein.

### DETAILED DESCRIPTION

Embodiments of the invention generally provide methods for forming silicon-based photovoltaic (PV) devices, such as PV or solar cells, and more specifically, to methods for treating transparent conductive oxide (TCO) layers with very high frequency (VHF) plasma treatment processes. The TCO layers generally contain zinc oxide or another transparent conductive oxide. The silicon-based PV devices have p-i-n junctions that contain layers of amorphous silicon (α-Si), microcrystalline silicon (μc-Si), polycrystalline silicon (poly-Si), and doped derivatives thereof. The VHF plasma treatments provide a reduction of the barrier height at the interface between the TCO layer and the p-type layer within a single junction PV cell (e.g., α-Si solar cell) or within a tandem junction PV cell, such as an α-Si/μc-Si tandem junction solar cell. The reduction of the barrier height at the TCO/p-type layer interface provides improved short circuit currents and fill factors resulting in improved conversion efficiency for the PV cell. The VHF plasma is generated in some examples by ionizing a process gas containing hydrogen gas (H₂) and nitrous oxide at an excitation frequency within a range from about 30 MHz to about 300 MHz.

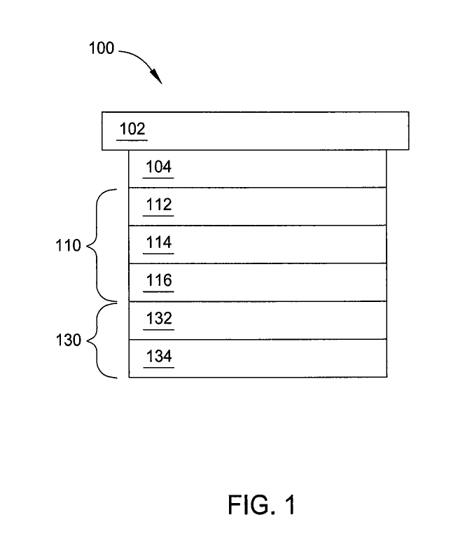

In one embodiment, a single junction PV cell, such as PV cell 100 depicted in FIG. 1, is fabricated or otherwise formed by conducting a VHF plasma treatment process described herein. FIG. 1 illustrates a cross-sectional view of a photovoltaic (PV) cell 100 containing a transparent substrate 102, as described in one embodiment herein. Generally, PV cell 100 is an amorphous silicon-based, thin film PV cell and transparent substrate 102 is utilized as a front-facing window of PV cell 100. PV cell 100 contains a transparent conductive oxide (TCO) layer 104, disposed on or over transparent substrate 102 a p-i-n junction 110 disposed on or over TCO layer 104, and a back reflector 130 disposed over p-i-n junction 110. Additionally, p-i-n junction 110 contains a p-type Si-based layer 112, an intrinsic Si-based layer 114, and an n-type Si-based layer 116 and back reflector 130 contains a transparent conductive oxide (TCO) layer 132 and a metallic reflective layer 134.

In some examples, TCO layer 104 is deposited or otherwise formed on or over an underlying surface of a substrate, such as transparent substrate 102, and subsequently, TCO layer 104 is exposed to a VHF plasma treatment. In other examples, TCO layer 132 is deposited or otherwise formed on or over an underlying layer, such as n-type Si-based layer 116 of p-i-n junction 110, and subsequently, TCO layer 132 is exposed to a VHF plasma treatment. Thereafter, metallic reflective layer 134 is formed on or over TCO layer 132 to complete assembly of back reflector 130. Each layer or film of material contained within p-i-n junction 110 may have a single layer or multiple layers. In one example, p-type Si-based layer 112 contains multiple p-type α-Si layers, intrinsic Si-based layer 114 contains multiple α-Si intrinsic layers, and n-type Si-based layer 116 contains multiple n-type α-Si layers.

Transparent substrate 102 is generally a pane, thin sheet or film, wafer, or other substrate utilized as a front-facing window of PV cell 100. Transparent substrate 102 contains a transparent material or material that is substantially transparent, such as glass, quartz, silicon, silicon oxide, silicon dioxide, plastic or polymeric material (e.g., polycarbonate), or other suitable material. Transparent substrate 102 generally has a surface area greater than about 0.1 m², such as within a range from about 0.5 m² to about 5 m², for example, about 1 m² or greater or about 2 m² or greater. It is to be understood that transparent substrate 102 may be referred to as a ‘superstrate’ in which the solar or PV cell is fabricated from the top down. During fabrication, transparent substrate 102 is typically referred to as a substrate, but then referred to as a ‘superstrate’ once the final PV device/product is turned over to face transparent substrate 102 above p-i-n junction 110. In some embodiments, the fabricated PV cell has a similar configuration as PV cell 100 such that transparent substrate 102 is a front-facing window (e.g., facing towards the sun) and contains transparent materials. In alternative embodiments, the fabricated photovoltaic cell has a different configuration as PV cell 100 such that transparent substrate 102 is a rear-facing window (e.g., facing away from the sun) and contains non-transparent materials.

PV cell 100 contains p-i-n junction 110 fabricated or otherwise formed on TCO layer 104 which is disposed on or over transparent substrate 102. The p-i-n junction 110 includes p-type Si-based layer 112, n-type Si-based layer 116, and an intrinsic type (i-type) Si-based layer 114 disposed between p-type Si-based layer 112 and n-type Si-based layer 116—as a photoelectric conversion layer. An optional dielectric layer (not shown) may be disposed between transparent substrate 102 and TCO layer 104. In some examples, the optional dielectric layer is a silicon-based layer containing amorphous or polysilicon, silicon oxynitride, silicon nitride, silicon carbide, silicon oxycarbide, silicon oxide layer, doped silicon layer, or another suitable silicon-containing layer. In other examples, the optional dielectric layer is a titanium-based layer, such as titanium oxide or titania, which has favorable barrier properties for impurities contained within transparent substrate 102.

TCO layer 104 contains or is fabricated from a metal oxide, or a mixture of metal oxides, which is electrically conductive and transparent. TCO layer 104 generally contain metal oxides of zinc, indium, tin, cadmium, aluminum, copper, gallium, alloys thereof, mixtures thereof, or combinations thereof. Exemplary metal oxides contained within TCO layer 104 include zinc oxide (e.g., ZnO), indium oxide (e.g., In₂O₃), tin oxide (e.g., SnO₂), indium tin oxide (ITO), cadmium oxide (CdO), cadmium stannate (e.g., Cd₂SnO₄), aluminum oxide or alumina (e.g., Al₂O₃), copper indium gallium selenide (CIGS—e.g., Culn₁₋ₓGaₓSe₂-based materials, where x is within a range from about 0.001 to about 0.999), cadmium telluride (e.g., CdSe-based materials), doped variants thereof, derivatives thereof, alloys thereof, or combinations thereof. TCO layer 104 contains at least one TCO material and may have additional dopants or elements, such as aluminum, gallium, boron, fluorine, sulfur, selenium, tellurium, or mixtures thereof. In some examples, TCO layer 104 contains zinc oxide and a dopant with a dopant concentration of about 5 at % (atomic percent) or less, such as about 2.5 at % or less. In some examples, TCO layer 104 contains a zinc oxide doped with aluminum oxide or alumina at the desired dopant concentration. In one example, TCO layer 104 contains zinc oxide doped with aluminum oxide at a dopant concentration of about 2.5 at %. In another example, TCO layer 104 contains tin oxide doped with fluorine.

TCO layer 104 is deposited or otherwise formed by a physical vapor deposition (PVD) process, an electroless chemical deposition/plating process, a chemical vapor deposition (CVD) process, a plasma enhanced chemical vapor deposition (PE-CVD) process, or another deposition process. In many examples, TCO layer 104 is fabricated by a sputter deposition process, wherein the TCO material is either sputtered from a metal oxide target or sputtered from a metallic target within an oxidizing environment, such as a chamber containing atomic oxygen, oxygen gas, ozone, nitrous oxide, derivatives thereof, or another oxidizing agent. In some examples, transparent substrate 102 having TCO layer 104 disposed thereon may be provided by a supplier (e.g., glass manufacturer). Several PVD processes which may be used to fabricate TCO materials for TCO layer 104 are further described in commonly assigned U.S. application Ser. Nos. 12/748,780 and 12/748,790, both filed Mar. 29, 2010, both entitled Method for Forming Transparent Conductive Oxide, and published as U.S. Pub. Nos. 2010-0311228 and 2010-0311204, which are incorporated by reference in their entirety to the extent not inconsistent with embodiments of the present disclosure.

TCO layer 104 disposed on or over transparent substrate 102 is exposed to a VHF plasma while forming a treated surface on TCO layer 104 during a plasma treatment process. Transparent substrate 102 containing TCO layer 104 is placed or otherwise positioned within a processing chamber enabled to perform the VHF plasma treatment. Subsequently, transparent substrate 102 containing TCO layer 104 is heated to a temperature of less than 500° C., such as within a range from about 100° C. to about 350° C. within the processing chamber. The processing chamber generally has an internal pressure during the VHF plasma treatment within a range from about 10 Pa to about 2,000 Pa.

The VHF plasma as described herein may be formed inside of a processing chamber, such as an in situ plasma, or may be formed outside of a processing chamber, such as with a remote plasma system (RPS), and transferred into the processing chamber. The processing chamber includes deposition chambers, plasma chambers, and other chambers containing and/or in fluid communication with a VHF plasma source, such as an RPS. The types of processing chambers that may be utilized to conduct the VHF plasma treatment include, but are not limited to CVD chambers, PE-CVD chambers, and plasma chambers. In some examples, an RPS that generates a VHF plasma is coupled with and in fluid communication to a deposition chamber, such as a CVD or PE-CVD chamber. Other variations of CVD or deposition chambers that ionize, generate, provide, or otherwise form a VHF plasma during the CVD process may also be utilized during the VHF plasma treatments described herein.

A single processing chamber or multiple processing chambers may be used to conduct the deposition processes (e.g., thermal CVD or PE-CVD) and plasma treatment processes (e.g., VHF or RF) described herein. Exemplary processing chambers include the PECVD 5.7™ chamber and the ATON™ CVD chamber, both manufactured by Applied Materials, Inc., located in Santa Clara, Calif., and an exemplary processing system is the SUNFAB™ solar module production line, also available from Applied Materials, Inc. Additional disclosure of deposition, plasma treatment, and other processing chambers and systems, as well as deposition and plasma treatment processes, and other processes utilized in the manufacturing of photovoltaic/solar devices and cells, as described herein, may be found in the commonly assigned U.S. Pat. Nos. 7,582,515 and 7,655,542, and U.S. application Ser. No. 12/178,289, filed Jul. 23, 2008, and published as U.S. Pub. No. 2009-0020154; U.S. application Ser. No. 12/564,697, filed Sep. 22, 2009, and published as U.S. Pub. No. 2010-0073011; and U.S. application Ser. No. 12/729,777, filed Mar. 23, 2010, and published as U.S. Pub. No. 2011-0232753, which are incorporated by reference in their entirety to the extent not inconsistent with embodiments of the present disclosure.

TCO layer 104 may be exposed to a process gas prior to, during, or subsequent to striking or otherwise generating the VHF plasma by ionizing (e.g., igniting) the process gas. The VHF plasma is generated by ionizing the process gas containing hydrogen gas (H₂) and an oxidizing gas, such as nitrous oxide (N₂O), oxygen gas (O₂), derivatives thereof, or combinations thereof. Optionally, a carrier gas may be included within the process gas or combined in the processing chamber with the hydrogen gas and the oxidizing gas. The carrier gas generally includes argon, neon, helium, nitrogen, or mixtures thereof. The hydrogen gas, the oxidizing gas, and optionally the carrier gas are generally combined to form the process gas prior to entering or within the processing chamber which is enabled to perform the VHF plasma treatment.

The hydrogen gas generally has a flow rate within a range from about 1 sccm to about 500 sccm, more narrowly within a range from about 2 sccm to about 200 sccm, more narrowly within a range from about 5 sccm to about 100 sccm, and more narrowly within a range from about 10 sccm to about 50 sccm, for example, about 25 sccm. The oxidizing gas or the nitrous oxide generally has a flow rate within from about 1 sccm to about 500 sccm, more narrowly within a range from about 2 sccm to about 300 sccm, more narrowly within a range from about 5 sccm to about 200 sccm, and more narrowly within a range from about 10 sccm to about 100 sccm, for example, about 50 sccm. The optional carrier gas, if utilized in the VHF plasma process, generally has a flow rate within a range from about 1 sccm to about 1,000 sccm, more narrowly within a range from about 1 sccm to about 500 sccm, more narrowly within a range from about 5 sccm to about 100 sccm, for example, about 50 sccm.

The process gas contains a mixture of hydrogen gas and an oxidizing gas having a molar concentration ratio of hydrogen relative to the oxidizing gas at about 0.5:10, such as about 1:1, or such as 10:0.5. In some embodiments, the process gas contains hydrogen gas and nitrous oxide at a H₂/N₂O concentration ratio of about 0.5:10, such as about 1:1, or such as 10:0.5. In one example, the H₂/N₂O concentration ratio is within a range from about 1:1 to about 10:1, for example, about 2:1.

The VHF plasma is generated by ionizing the process gas containing hydrogen gas and an oxidizing gas (e.g., N₂O or O₂) at an excitation frequency within a range from about 30 MHz to about 300 MHz and exposed to TCO layer 104. The VHF plasma source is generally set to generate the VHF plasma at an excitation frequency greater than 30 MHz and less than 300 MHz, for example, within a range from about 40 MHz to about 150 MHz, and more narrowly within a range from about 50 MHz to about 100 MHz, such as about 65 MHz or about 78 MHz. In some examples, the VHF plasma is formed by an excitation frequency of about 65 MHz or about 78 MHz. The power level of the VHF plasma is generally within a range from about 0.01 W/cm² to about 10.0 W/cm², and more narrowly within a range from about 0.1 W/cm² to about 5.0 W/cm². TCO layer 104 is usually exposed to the VHF plasma for a time period within a range from about 1 second to about 120 seconds, more narrowly within a range from about 10 seconds to about 60 seconds, and more narrowly within a range from about 20 seconds to about 40 seconds, for example, about 30 seconds. In other examples, TCO layer 104 is exposed to the VHF plasma for a time period within a range from about 0.5 seconds to about 60 seconds, more narrowly within a range from about 2 seconds to about 30 seconds, and more narrowly within a range from about 5 seconds to about 20 seconds, for example, about 10 seconds. A treated surface of TCO layer 104 is formed during the VHF plasma treatment process and provides an interface between TCO layer 104 and p-type Si-based layer 112 disposed thereon.

In one embodiment, the VHF plasma treatment process is utilized to reduce the barrier height at the TCO/p-type layer interface within a single junction, α-Si solar cell, such as PV cell 100. The interface between TCO layer 104 and p-type Si-based layer 112 contains a reduce the barrier height at the VHF plasma treated surface of TCO layer 104. The reduction of the barrier height at the TCO/p-type layer interface provides improved short circuit currents and fill factors resulting in improved conversion efficiency for PV cell 100.

The p-type Si-based layer 112 contains a silicon-based material such as amorphous silicon (α-Si), polycrystalline silicon (poly-Si), microcrystalline silicon (μc-Si), or combinations thereof, which is generally doped with at least one Group III element. In many examples, the silicon-based materials contained within p-type Si-based layer 112 are amorphous silicon materials. The silicon-based material, layer, or film doped with the Group III element is referred to as a p-doped or a p-type silicon material, layer, or film. In one example, p-type Si-based layer 112 contains a boron doped, amorphous silicon material. Alternatively, p-type Si-based layer 112 may be doped with other elements selected to meet desired specifications for PV cell 100. The p-type Si-based layer 112 is generally deposited or otherwise formed by a PE-CVD process or similar deposition process. The p-type Si-based layer 112 generally has a thickness within a range from about 10 Å and about 500 Å, more narrowly within a range from about 20 Å to about 300 Å, and more narrowly within a range from about 30 Å to about 200 Å.

Intrinsic Si-based layer 114 is generally an undoped-type, silicon-based layer or film disposed between p-type Si-based layer 112 and n-type Si-based layer 116. Intrinsic Si-based layer 114 is deposited or otherwise formed on or over p-type Si-based layer 112. Intrinsic Si-based layer 114 provides efficient photoelectric conversion for PV cell 100. In many examples, intrinsic Si-based layer 114 contains or is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). Intrinsic Si-based layer 114 is generally deposited or otherwise formed by a PE-CVD process or similar deposition process. Intrinsic Si-based layer 114 generally has a thickness within a range from about 10 Å and about 500 Å, more narrowly within a range from about 20 Å to about 300 Å, and more narrowly within a range from about 30 Å to about 200 Å.

The n-type Si-based layer 116 contains a silicon-based material such as amorphous silicon (α-Si), polycrystalline silicon (poly-Si), microcrystalline silicon (μc-Si), or combinations thereof, which is generally doped with at least one Group V element. In some examples, n-type Si-based layer 116 contains n-doped amorphous silicon. The silicon-based material, layer, or film doped with the Group V element is referred to as an n-doped or an n-type silicon material, layer, or film. In other examples, n-type Si-based layer 116 contains a phosphorus doped, amorphous silicon material. Alternatively, n-type Si-based layer 116 may be doped with other elements selected to meet desired specifications for PV cell 100. The n-type Si-based layer 116 is generally deposited or otherwise formed by a PE-CVD process or similar deposition process. The n-type Si-based layer 116 generally has a thickness within a range from about 10 Å and about 500 Å, more narrowly within a range from about 20 Å to about 300 Å, and more narrowly within a range from about 30 Å to about 200 Å.

Subsequent the formation of p-i-n junction 110 on TCO layer 104, back reflector 130 is deposited or otherwise formed over p-i-n junction 110. Generally, back reflector 130 contains a stacked film that includes metallic reflective layer 134 disposed on a TCO layer 132 disposed on the upper surface of p-i-n junction 110, such as n-type Si-based layer 116.

TCO layer 132 may be independently fabricated or contain the same metal oxide or a different metal oxide as TCO layer 104. TCO layer 132 contains or is fabricated from a metal oxide such as tin oxide, indium tin oxide, zinc oxide, cadmium stannate, aluminum oxide or alumina, doped variants thereof, derivatives thereof, alloys thereof, or combinations thereof. TCO layer 132 contains at least one TCO material and may have additional dopants or elements, such as aluminum, gallium, boron, fluorine, or mixtures thereof. In some examples, TCO layer 132 contains zinc oxide and a dopant and has a dopant concentration of about 5 at % (atomic percent) or less, such as about 2.5 at % or less. In other examples, TCO layer 132 contains a zinc oxide doped with aluminum oxide or alumina at the desired dopant concentration. In one example, TCO layer 132 contains zinc oxide doped with aluminum oxide at a dopant concentration of about 2.5 at %. In another example, TCO layer 132 contains tin oxide doped with fluorine. TCO layer 132 is generally deposited, fabricated, or otherwise formed by a sputter deposition process, wherein the TCO material is either sputtered from a metal oxide target or sputtered from a metallic target within an oxidizing environment, such as a chamber containing atomic oxygen, oxygen gas, ozone, nitrous oxide, derivatives thereof, or another oxidizing agent.

In one embodiment, TCO layer 132 is exposed to a VHF plasma treatment process to form a treated surface of TCO layer 132 prior to depositing metallic reflective layer 134 on or over TCO layer 132. The VHF plasma treatment process may be the same plasma treatment or a different plasma treatment as conducted on TCO layer 104. In general, the VHF plasma is generated by ionizing a process gas containing hydrogen gas (H₂) and nitrous oxide at an excitation frequency within a range from about 30 MHz to about 300 MHz and more narrowly within a range from about 40 MHz to about 150 MHz.

Metallic reflective layer 134 contained within back reflector 130 is deposited or otherwise formed on or over TCO layer 132. In one embodiment, a treated surface of TCO layer 132 is formed by exposure to a VHF plasma and thereafter, metallic reflective layer 134 is formed on the treated surface of TCO layer 132. Metallic reflective layer 134 is generally formed by a PVD process, a CVD process, a PE-CVD process, an electrochemical deposition process, an electroless deposition process, or a combination of two or more deposition or plating processes. Metallic reflective layer 134 generally contains or is fabricated from at least one metal, such as titanium, chromium, aluminum, nickel, silver, gold, copper, platinum, palladium, ruthenium, alloys thereof, or combinations thereof.

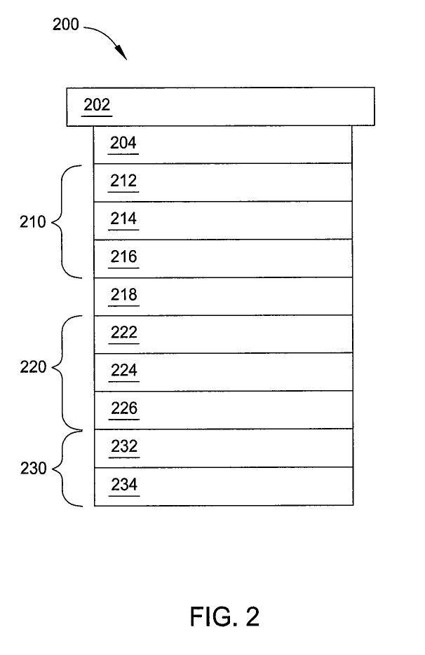

FIG. 2 depicts an exemplary cross-sectional view of a tandem-type photovoltaic (PV) cell 200, such as a silicon-based, thin film PV cell, fabricated in accordance with another embodiment of the invention. Tandem-type PV cell 200 shares some common structures, layers, and materials with PV cell 100 including a transparent conductive oxide (TCO) layer 204 formed on a transparent substrate 202 and a first p-i-n junction 210 formed on TCO layer 204. First p-i-n junction 210 generally contains layers and/or materials as described with reference to p-i-n junction 110 of FIG. 1, such as the doped and non-doped silicon-based materials which include amorphous silicon (α-Si), hydrogenated amorphous silicon (α-Si:H), polycrystalline silicon (poly-Si), and/or microcrystalline silicon (μc-Si).

In general, PV cell 200 contains TCO layer 204 disposed on or over transparent substrate 202, and a first p-i-n junction 210 disposed on or over TCO layer 204. First p-i-n junction 210 contains a p-type Si-based layer 212, an intrinsic Si-based layer 214, and an n-type Si-based layer 216. Additionally, PV cell 200 contains an intermediate TCO layer 218 disposed on or over first p-i-n junction 210, a second p-i-n junction 220 disposed on or over intermediate TCO layer 218, and a back reflector 230 disposed on or over second p-i-n junction 220. Second p-i-n junction 220 contains a p-type Si-based layer 222, an intrinsic Si-based layer 224, and an n-type Si-based layer 226. Back reflector 230 contains a TCO layer 232 and a metallic reflective layer 234. In some examples, PV cell 200 is an α-Si/μc-Si tandem junction solar cell—such that first p-i-n junction 210 contains an α-Si junction and second p-i-n junction 220 contains a μc-Si junction.

TCO layer 204 is generally deposited or otherwise formed on or over an underlying surface of a substrate, such as transparent substrate 202, and subsequently, TCO layer 204 is exposed to a VHF plasma treatment. In other examples, intermediate TCO layer 218 is deposited or otherwise formed on or over an underlying layer, such as n-type Si-based layer 216 of first p-i-n junction 210, and subsequently, intermediate TCO layer 218 is exposed to a VHF plasma treatment. Thereafter, p-type Si-based layer 222 is deposited or otherwise formed on or over intermediate TCO layer 218. Back reflector 230 is deposited or otherwise formed on or over second p-i-n junction 220 of PV cell 200. In other examples, TCO layer 232 is deposited or otherwise formed on or over an underlying layer, such as n-type Si-based layer 226 of second p-i-n junction 220, and subsequently, TCO layer 232 is exposed to a VHF plasma treatment. Thereafter, metallic reflective layer 234 is deposited or otherwise formed on or over TCO layer 232 to complete assembly of back reflector 230.

Transparent substrate 202 is generally a pane, thin sheet or film, wafer, or other substrate utilized as a front-facing window of PV cell 200. Transparent substrate 202 contains a transparent material or material that is substantially transparent, such as glass, quartz, silicon, silicon oxide, silicon dioxide, plastic or polymeric material (e.g., polycarbonate), or other suitable material. Transparent substrate 202 generally has a surface area greater than about 0.1 m², such as within a range from about 0.5 m² to about 5 m², for example, about 1 m² or greater or about 2 m² or greater. It is to be understood that transparent substrate 202 may be referred to as a ‘superstrate’ in which the solar or PV cell is fabricated from the top down. During fabrication, transparent substrate 202 is typically referred to as a substrate, but then referred to as a ‘superstrate’ once the final PV device/product is turned over to face transparent substrate 202 above first p-i-n junction 210. In some embodiments, the fabricated PV cell has a similar configuration as PV cell 200 such that transparent substrate 202 is a front-facing window (e.g., facing towards the sun) and contains transparent materials. In alternative embodiments, the fabricated photovoltaic cell has a different configuration as PV cell 200 such that transparent substrate 202 is a rear-facing window (e.g., facing away from the sun) and contains non-transparent materials.

An optional dielectric layer (not shown) may be disposed between transparent substrate 202 and TCO layer 204. In some examples, the optional dielectric layer is a silicon-based layer containing amorphous or polysilicon, silicon oxynitride, silicon nitride, silicon carbide, silicon oxycarbide, silicon oxide layer, doped silicon layer, or another suitable silicon-containing layer. In other examples, the optional dielectric layer is a titanium-based layer, such as titanium oxide or titania, which has favorable barrier properties for impurities contained within transparent substrate 202.

TCO layer 204 contains or is fabricated from a metal oxide, or a mixture of metal oxides, which is electrically conductive and transparent. TCO layer 204 generally contain metal oxides of zinc, indium, tin, cadmium, aluminum, copper, gallium, alloys thereof, mixtures thereof, or combinations thereof. Exemplary metal oxides contained within TCO layer 204 include zinc oxide (e.g., ZnO), indium oxide (e.g., In₂O₃), tin oxide (e.g., SnO₂), indium tin oxide (ITO), cadmium oxide (CdO), cadmium stannate (e.g., Cd₂SnO₄), aluminum oxide or alumina (e.g., Al₂O₃), copper indium gallium selenide (CIGS—e.g., Culn₁₋ₓGaₓSe₂-based materials, where x is within a range from about 0.001 to about 0.999), cadmium telluride (e.g., CdSe-based materials), doped variants thereof, derivatives thereof, alloys thereof, or combinations thereof. TCO layer 204 contains at least one TCO material and may have additional dopants or elements, such as aluminum, gallium, boron, fluorine, sulfur, selenium, tellurium, or mixtures thereof. In some examples, TCO layer 204 contains zinc oxide and a dopant with a dopant concentration of about 5 at % (atomic percent) or less, such as about 2.5 at % or less. In some examples, TCO layer 204 contains a zinc oxide doped with aluminum oxide or alumina at the desired dopant concentration. In one example, TCO layer 204 contains zinc oxide doped with aluminum oxide at a dopant concentration of about 2.5 at %. In another example, TCO layer 204 contains tin oxide doped with fluorine.

TCO layer 204 is deposited or otherwise formed by a PVD process, an electroless chemical deposition/plating process, a CVD process, a PE-CVD process, or another deposition process. In many examples, TCO layer 204 is fabricated by a sputter deposition process, wherein the TCO material is either sputtered from a metal oxide target or sputtered from a metallic target within an oxidizing environment, such as a chamber containing atomic oxygen, oxygen gas, ozone, nitrous oxide, derivatives thereof, or another oxidizing agent. In some examples, transparent substrate 202 having TCO layer 204 disposed thereon may be provided by a supplier (e.g., glass manufacturer). Several PVD processes which may be used to fabricate TCO materials for TCO layer 204 are further described in commonly assigned U.S. application Ser. Nos. 12/748,780 and 12/748,790, both filed Mar. 29, 2010, both entitled Method for Forming Transparent Conductive Oxide, and published as U.S. Pub. Nos. 2010-0311228 and 2010-0311204, which are incorporated by reference in their entirety to the extent not inconsistent with embodiments of the present disclosure.

TCO layer 204 disposed on or over transparent substrate 202 is exposed to a VHF plasma while forming a treated surface on TCO layer 204 during a plasma treatment process. Transparent substrate 202 containing TCO layer 204 is placed or otherwise positioned within a processing chamber enabled to perform the VHF plasma treatment. Subsequently, transparent substrate 202 containing TCO layer 204 is heated to a temperature of less than 500° C., such as within a range from about 100° C. to about 350° C. within the processing chamber. The processing chamber generally has an internal pressure during the VHF plasma treatment within a range from about 10 Pa to about 2,000 Pa.

TCO layer 204 may be exposed to a process gas prior to, during, or subsequent to striking or otherwise generating the VHF plasma by ionizing (e.g., igniting) the process gas. The VHF plasma is generated by ionizing the process gas containing hydrogen gas (H₂) and an oxidizing gas, such as nitrous oxide, oxygen gas (O₂), derivatives thereof, or combinations thereof. Optionally, a carrier gas may be included within the process gas or combined in the processing chamber with the hydrogen gas and the oxidizing gas. The carrier gas generally includes argon, neon, helium, nitrogen, or mixtures thereof. The hydrogen gas, the oxidizing gas, and optionally the carrier gas are generally combined to form the process gas prior to entering or within the processing chamber which is enabled to perform the VHF plasma treatment.

The hydrogen gas generally has a flow rate within a range from about 1 sccm to about 500 sccm, more narrowly within a range from about 2 sccm to about 200 sccm, more narrowly within a range from about 5 sccm to about 100 sccm, and more narrowly within a range from about 10 sccm to about 50 sccm, for example, about 25 sccm. The oxidizing gas or the nitrous oxide generally has a flow rate within from about 1 sccm to about 500 sccm, more narrowly within a range from about 2 sccm to about 300 sccm, more narrowly within a range from about 5 sccm to about 200 sccm, and more narrowly within a range from about 10 sccm to about 100 sccm, for example, about 50 sccm. The optional carrier gas, if utilized in the VHF plasma process, generally has a flow rate within a range from about 1 sccm to about 1,000 sccm, more narrowly within a range from about 1 sccm to about 500 sccm, more narrowly within a range from about 5 sccm to about 100 sccm, for example, about 50 sccm.

The process gas contains a mixture of hydrogen gas and an oxidizing gas having a molar concentration ratio of hydrogen relative to the oxidizing gas at about 0.5:10, such as about 1:1, or such as 10:0.5. In some embodiments, the process gas contains hydrogen gas and nitrous oxide at a H₂/N₂O concentration ratio of about 0.5:10, such as about 1:1, or such as 10:0.5. In one example, the H₂/N₂O concentration ratio is within a range from about 1:1 to about 10:1, for example, about 2:1.

The VHF plasma is generated by ionizing the process gas containing hydrogen gas and an oxidizing gas (e.g., N₂O or O₂) at an excitation frequency within a range from about 30 MHz to about 300 MHz and exposed to TCO layer 204. The VHF plasma source is generally set to generate the VHF plasma at an excitation frequency greater than 30 MHz and less than 300 MHz, for example, within a range from about 40 MHz to about 150 MHz, and more narrowly within a range from about 50 MHz to about 100 MHz, such as about 65 MHz or about 78 MHz. In some examples, the VHF plasma is formed by an excitation frequency of about 65 MHz or about 78 MHz. The power level of the VHF plasma is generally within a range from about 0.01 W/cm² to about 10.0 W/cm², and more narrowly within a range from about 0.1 W/cm² to about 5.0 W/cm². TCO layer 204 is usually exposed to the VHF plasma for a time period within a range from about 1 second to about 120 seconds, more narrowly within a range from about 10 seconds to about 60 seconds, and more narrowly within a range from about 20 seconds to about 40 seconds, for example, about 30 seconds. In other examples, TCO layer 204 is exposed to the VHF plasma for a time period within a range from about 0.5 seconds to about 60 seconds, more narrowly within a range from about 2 seconds to about 30 seconds, and more narrowly within a range from about 5 seconds to about 20 seconds, for example, about 10 seconds. A treated surface of TCO layer 204 is formed during the VHF plasma treatment process and provides an interface between TCO layer 204 and p-type Si-based layer 212 disposed thereon.

In another embodiment, the VHF plasma treatment process is utilized to reduce the barrier height at the TCO/p-type layer interface within the first p-i-n junction 210 of PV cell 200—an α-Si/μc-Si tandem junction solar cell. The interface between TCO layer 204 and p-type Si-based layer 212 contains a reduce the barrier height at the VHF plasma treated surface of TCO layer 204. The p-type Si-based layer 212—as well as the other layers within the first p-i-n junction 210—generally contains amorphous silicon. The reduction of the barrier height at the TCO/p-type α-Si layer interface provides improved short circuit currents and fill factors resulting in improved conversion efficiency for PV cell 200.

The p-type Si-based layer 212 contains a silicon-based material such as amorphous silicon (α-Si), polycrystalline silicon (poly-Si), microcrystalline silicon (μc-Si), or combinations thereof, which is generally doped with at least one Group III element. In many examples, the silicon-based materials contained within p-type Si-based layer 212 are amorphous silicon materials. The silicon-based material, layer, or film doped with the Group III element is referred to as a p-doped or a p-type silicon material, layer, or film. In one example, p-type Si-based layer 212 contains a boron doped, amorphous silicon material. Alternatively, p-type Si-based layer 212 may be doped with other elements selected to meet desired specifications for PV cell 200. The p-type Si-based layer 212 is generally deposited or otherwise formed by a PE-CVD process or similar deposition process. The p-type Si-based layer 212 generally has a thickness within a range from about 10 Å and about 500 Å, more narrowly within a range from about 20 Å to about 300 Å, and more narrowly within a range from about 30 Å to about 200 Å.

Intrinsic Si-based layer 214 is generally an undoped-type, silicon-based layer or film disposed between p-type Si-based layer 212 and n-type Si-based layer 216. Intrinsic Si-based layer 214 is deposited or otherwise formed on or over p-type Si-based layer 212. Intrinsic Si-based layer 214 provides efficient photoelectric conversion for PV cell 200. In many examples, intrinsic Si-based layer 214 contains or is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). Intrinsic Si-based layer 214 is generally deposited or otherwise formed by a PE-CVD process or similar deposition process. Intrinsic Si-based layer 214 generally has a thickness within a range from about 10 Å and about 500 Å, more narrowly within a range from about 20 Å to about 300 Å, and more narrowly within a range from about 30 Å to about 200 Å.

The n-type Si-based layer 216 contains a silicon-based material such as amorphous silicon (α-Si), polycrystalline silicon (poly-Si), microcrystalline silicon (μc-Si), or combinations thereof, which is generally doped with at least one Group V element. In some examples, n-type Si-based layer 216 contains n-doped amorphous silicon. The silicon-based material, layer, or film doped with the Group V element is referred to as an n-doped or an n-type silicon material, layer, or film. In other examples, n-type Si-based layer 216 contains a phosphorus doped, amorphous silicon material. Alternatively, n-type Si-based layer 216 may be doped with other elements selected to meet desired specifications for PV cell 200. The n-type Si-based layer 216 is generally deposited or otherwise formed by a PE-CVD process or similar deposition process. The n-type Si-based layer 216 generally has a thickness within a range from about 10 Å and about 500 Å, more narrowly within a range from about 20 Å to about 300 Å, and more narrowly within a range from about 30 Å to about 200 Å.

An intermediate TCO layer 218 is disposed between first p-i-n junction 210 and second p-i-n junction 220. Intermediate TCO layer 218 contains a TCO material or layer and is formed on or over first p-i-n junction 210, thereafter, second p-i-n junction 220 is formed on or over intermediate TCO layer 218. The combination of first p-i-n junction 210 and second p-i-n junction 220 as depicted in FIG. 2 increases the overall photoelectric conversion efficiency of PV cell 200.

Intermediate TCO layer 218 may be independently fabricated or contain the same metal oxide or a different metal oxide as TCO layer 204. Intermediate TCO layer 218 contains or is fabricated from a metal oxide such as tin oxide, indium tin oxide, zinc oxide, cadmium stannate, aluminum oxide or alumina, doped variants thereof, derivatives thereof, alloys thereof, or combinations thereof. Intermediate TCO layer 218 contains at least one TCO material and may have additional dopants or elements, such as aluminum, gallium, boron, fluorine, or mixtures thereof. In some examples, intermediate TCO layer 218 may contain zinc oxide with a dopant concentration of about 5 at % (atomic percent) or less, such as about 2.5 at % or less. In some examples, intermediate TCO layer 218 contains a zinc oxide doped with aluminum oxide or alumina at the desired dopant concentration. In one example, intermediate TCO layer 218 contains zinc oxide doped with aluminum oxide at a dopant concentration of about 2.5 at %. In another example, intermediate TCO layer 218 contains tin oxide doped with fluorine. Intermediate TCO layer 218 is generally deposited, fabricated, or otherwise formed by a sputter deposition process, wherein the TCO material is either sputtered from a metal oxide target or sputtered from a metallic target within an oxidizing environment, such as a chamber containing atomic oxygen, oxygen gas, ozone, nitrous oxide, derivatives thereof, or another oxidizing agent.

Intermediate TCO layer 218 contained on first p-i-n junction 210 is exposed to a VHF plasma while forming a treated surface on intermediate TCO layer 218 during a plasma treatment process. Transparent substrate 202 containing first p-i-n junction 210 and intermediate TCO layer 218 disposed thereon is placed or otherwise positioned within a processing chamber enabled to perform the VHF plasma treatment. Subsequently, transparent substrate 202 containing intermediate TCO layer 218 is heated to a temperature of less than 500° C., such as within a range from about 100° C. to about 350° C. within the processing chamber. The processing chamber generally has an internal pressure during the VHF plasma treatment within a range from about 10 Pa to about 2,000 Pa.

Intermediate TCO layer 218 may be exposed to a process gas prior to, during, or subsequent to striking or otherwise generating the VHF plasma by ionizing (e.g., igniting) the process gas. The VHF plasma is generated by ionizing the process gas containing hydrogen gas (H₂) and an oxidizing gas, such as nitrous oxide, oxygen gas (O₂), derivatives thereof, or combinations thereof. Optionally, a carrier gas may be included within the process gas or combined in the processing chamber with the hydrogen gas and the oxidizing gas. The carrier gas generally includes argon, neon, helium, nitrogen, or mixtures thereof. The hydrogen gas, the oxidizing gas, and optionally the carrier gas are generally combined to form the process gas prior to entering or within the processing chamber which is enabled to perform the VHF plasma treatment.

The hydrogen gas generally has a flow rate within a range from about 1 sccm to about 500 sccm, more narrowly within a range from about 2 sccm to about 200 sccm, more narrowly within a range from about 5 sccm to about 100 sccm, and more narrowly within a range from about 10 sccm to about 50 sccm, for example, about 25 sccm. The oxidizing gas or the nitrous oxide generally has a flow rate within from about 1 sccm to about 500 sccm, more narrowly within a range from about 2 sccm to about 300 sccm, more narrowly within a range from about 5 sccm to about 200 sccm, and more narrowly within a range from about 10 sccm to about 100 sccm, for example, about 50 sccm. The optional carrier gas, if utilized in the VHF plasma process, generally has a flow rate within a range from about 1 sccm to about 1,000 sccm, more narrowly within a range from about 1 sccm to about 500 sccm, more narrowly within a range from about 5 sccm to about 100 sccm, for example, about 50 sccm.

The process gas contains a mixture of hydrogen gas and an oxidizing gas having a molar concentration ratio of hydrogen relative to the oxidizing gas at about 0.5:10, such as about 1:1, or such as 10:0.5. In some embodiments, the process gas contains hydrogen gas and nitrous oxide at a H₂/N₂O concentration ratio of about 0.5:10, such as about 1:1, or such as 10:0.5. In one example, the H₂/N₂O concentration ratio is within a range from about 1:1 to about 10:1, for example, about 2:1.

The VHF plasma is generated by ionizing the process gas containing hydrogen gas and an oxidizing gas (e.g., N₂O or O₂) at an excitation frequency within a range from about 30 MHz to about 300 MHz and exposed to intermediate TCO layer 218. The VHF plasma source is generally set to generate the VHF plasma at an excitation frequency greater than 30 MHz and less than 300 MHz, for example, within a range from about 40 MHz to about 150 MHz, and more narrowly within a range from about 50 MHz to about 100 MHz, such as about 65 MHz or about 78 MHz. In some examples, the VHF plasma is formed by an excitation frequency of about 65 MHz or about 78 MHz. The power level of the VHF plasma is generally within a range from about 0.01 W/cm² to about 10.0 W/cm², and more narrowly within a range from about 0.1 W/cm² to about 5.0 W/cm². Intermediate TCO layer 218 is usually exposed to the VHF plasma for a time period within a range from about 1 second to about 120 seconds, more narrowly within a range from about 10 seconds to about 60 seconds, and more narrowly within a range from about 20 seconds to about 40 seconds, for example, about 30 seconds. In other examples, intermediate TCO layer 218 is exposed to the VHF plasma for a time period within a range from about 0.5 seconds to about 60 seconds, more narrowly within a range from about 2 seconds to about 30 seconds, and more narrowly within a range from about 5 seconds to about 20 seconds, for example, about 10 seconds. A treated surface of intermediate TCO layer 218 is formed during the VHF plasma treatment process and provides an interface between intermediate TCO layer 218 and p-type Si-based layer 222 disposed thereon.

In another embodiment, the VHF plasma treatment process is utilized to reduce the barrier height at the TCO/p-type layer interface within the second p-i-n junction 220 of PV cell 200—an α-Si/μc-Si tandem junction solar cell. The interface between intermediate TCO layer 218 and p-type Si-based layer 222 contains a reduce the barrier height at the VHF plasma treated surface of intermediate TCO layer 218. The p-type Si-based layer 222—as well as the other layers within the second p-i-n junction 220—generally contains microcrystalline silicon. The reduction of the barrier height at the TCO/p-type μc-Si layer interface provides improved short circuit currents and fill factors resulting in improved conversion efficiency for PV cell 200.

FIG. 2 further depicts that second p-i-n junction 220 contains intrinsic Si-based layer 224 disposed between p-type Si-based layer 222 and n-type Si-based layer 226. The p-type Si-based layer 222, intrinsic Si-based layer 224, and n-type Si-based layer 226 each may independently contain μc-Si-based materials, polysilicon-based materials, amorphous Si-based materials, or combinations thereof. In some examples, p-type Si-based layer 222 contains p-doped μc-Si, intrinsic Si-based layer 224 contains undoped μc-Si, and n-type Si-based layer 226 contains n-doped μc-Si.

The p-type Si-based layer 222 contains a silicon-based material such as amorphous silicon (α-Si), polycrystalline silicon (poly-Si), microcrystalline silicon (μc-Si), or combinations thereof, which is generally doped with at least one Group III element. In many examples, the silicon-based materials contained within p-type Si-based layer 222 are amorphous silicon materials. The silicon-based material, layer, or film doped with the Group III element is referred to as a p-doped or a p-type silicon material, layer, or film. In one example, p-type Si-based layer 222 contains a boron doped, amorphous silicon material. Alternatively, p-type Si-based layer 222 may be doped with other elements selected to meet desired specifications for PV cell 200. The p-type Si-based layer 222 is generally deposited or otherwise formed by a PE-CVD process or similar deposition process. The p-type Si-based layer 222 generally has a thickness within a range from about 10 Å and about 500 Å, more narrowly within a range from about 20 Å to about 300 Å, and more narrowly within a range from about 30 Å to about 200 Å.

Intrinsic Si-based layer 224 is generally an undoped-type, silicon-based layer or film disposed between p-type Si-based layer 222 and n-type Si-based layer 226. Intrinsic Si-based layer 224 is deposited or otherwise formed on or over p-type Si-based layer 222. Intrinsic Si-based layer 224 provides efficient photoelectric conversion for PV cell 200. In many examples, intrinsic Si-based layer 224 contains or is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). Intrinsic Si-based layer 224 is generally deposited or otherwise formed by a PE-CVD process or similar deposition process. Intrinsic Si-based layer 224 generally has a thickness within a range from about 10 Å and about 500 Å, more narrowly within a range from about 20 Å to about 300 Å, and more narrowly within a range from about 30 Å to about 200 Å.

The n-type Si-based layer 226 contains a silicon-based material such as amorphous silicon (α-Si), polycrystalline silicon (poly-Si), microcrystalline silicon (μc-Si), or combinations thereof, which is generally doped with at least one Group V element. In some examples, n-type Si-based layer 226 contains n-doped amorphous silicon. The silicon-based material, layer, or film doped with the Group V element is referred to as an n-doped or an n-type silicon material, layer, or film. In other examples, n-type Si-based layer 226 contains a phosphorus doped, amorphous silicon material. Alternatively, n-type Si-based layer 226 may be doped with other elements selected to meet desired specifications for PV cell 200. The n-type Si-based layer 226 is generally deposited or otherwise formed by a PE-CVD process or similar deposition process. The n-type Si-based layer 226 generally has a thickness within a range from about 10 Å and about 500 Å, more narrowly within a range from about 20 Å to about 300 Å, and more narrowly within a range from about 30 Å to about 200 Å.

A back reflector 230 is disposed on second p-i-n junction 220. Back reflector 230 may be similar to back reflector 130 as described with reference to FIG. 1. Back reflector 230 may contains a metallic reflective layer 234 formed on a top TCO layer 232. The materials of metallic reflective layer 234 and TCO layer 232 may be similar to metallic reflective layer 134 and TCO layer 132 as described with reference to FIG. 1.

Subsequent the formation of second p-i-n junction 220 on intermediate TCO layer 218, back reflector 230 is deposited or otherwise formed over second p-i-n junction 220. Generally, back reflector 230 contains a stacked film that includes metallic reflective layer 234 disposed on a TCO layer 232 disposed on the upper surface of second p-i-n junction 220, such as n-type Si-based layer 226.

TCO layer 232 may be independently fabricated or contain the same metal oxide or a different metal oxide as TCO layer 204. TCO layer 232 contains or is fabricated from a metal oxide such as tin oxide, indium tin oxide, zinc oxide, cadmium stannate, aluminum oxide or alumina, doped variants thereof, derivatives thereof, alloys thereof, or combinations thereof. TCO layer 232 contains at least one TCO material and may have additional dopants or elements, such as aluminum, gallium, boron, fluorine, or mixtures thereof. In some examples, TCO layer 232 contains zinc oxide and a dopant and has a dopant concentration of about 5 at % (atomic percent) or less, such as about 2.5 at % or less. In other examples, TCO layer 232 contains a zinc oxide doped with aluminum oxide or alumina at the desired dopant concentration. In one example, TCO layer 232 contains zinc oxide doped with aluminum oxide at a dopant concentration of about 2.5 at %. In another example, TCO layer 232 contains tin oxide doped with fluorine. TCO layer 232 is generally deposited, fabricated, or otherwise formed by a sputter deposition process, wherein the TCO material is either sputtered from a metal oxide target or sputtered from a metallic target within an oxidizing environment, such as a chamber containing atomic oxygen, oxygen gas, ozone, nitrous oxide, derivatives thereof, or another oxidizing agent.

In one embodiment, TCO layer 232 is exposed to a VHF plasma treatment process a treated surface of TCO layer 232 prior to depositing metallic reflective layer 234 on or over TCO layer 232. The VHF plasma treatment process may be the same plasma treatment or a different plasma treatment as conducted on TCO layer 204. In general, the VHF plasma is generated by ionizing a process gas containing hydrogen gas (H₂) and nitrous oxide at an excitation frequency within a range from about 30 MHz to about 300 MHz and more narrowly within a range from about 40 MHz to about 150 MHz.

Metallic reflective layer 234 contained within back reflector 130 is deposited or otherwise formed on or over TCO layer 232. In one embodiment, a treated surface of TCO layer 232 is formed by exposure to a VHF plasma and thereafter, metallic reflective layer 234 is formed on the treated surface of TCO layer 232. Metallic reflective layer 234 is generally formed by a PVD process, a CVD process, a PE-CVD process, an electrochemical deposition process, an electroless deposition process, or a combination of two or more deposition or plating processes. Metallic reflective layer 234 generally contains or is fabricated from at least one metal, such as titanium, chromium, aluminum, nickel, silver, gold, copper, platinum, palladium, ruthenium, alloys thereof, or combinations thereof.

While the foregoing is directed to embodiments of the invention, other and further embodiments of the invention may be devised without departing from the basic scope thereof, and the scope thereof is determined by the claims that follow.

1. A method for forming a silicon-based photovoltaic device, comprising:
depositing a transparent conductive oxide layer on an underlying surface, wherein the transparent conductive oxide layer comprises zinc oxide;
exposing the transparent conductive oxide layer to a very high frequency (VHF) plasma to form a treated surface on the transparent conductive oxide layer during a plasma treatment process, wherein the VHF plasma is generated by ionizing a process gas comprising hydrogen (H₂) and nitrous oxide at an excitation frequency within a range from about 30 MHz to about 300 MHz;
forming a p-type Si-based layer over the treated surface of the transparent conductive oxide layer;
forming an intrinsic Si-based layer over the p-type Si-based layer; and
forming an n-type Si-based layer over the intrinsic Si-based layer.

2. The method of claim 1, wherein the excitation frequency is within a range from about 40 MHz to about 150 MHz.

3. The method of claim 2, wherein a power level of the VHF plasma is within a range from about 0.1 W/cm² to about 5.0 W/cm².

4. The method of claim 2, wherein the transparent conductive oxide layer is exposed to the VHF plasma for a time period within a range from about 2 seconds to about 30 seconds.

5. The method of claim 1, wherein the process gas comprises the hydrogen and the nitrous oxide at a H₂/N₂O concentration ratio within a range from about 1:1 to about 10:1.

6. The method of claim 1, wherein the underlying surface is a transparent substrate comprising a material selected from the group consisting of glass, quartz, silicon, silicon oxide, polymeric, oligomeric, and derivatives thereof.

7. The method of claim 1, wherein the underlying surface is an underlying layer comprising an n-type material contained within a p-i-n junction.

8. The method of claim 7, wherein the n-type material comprises an n-doped amorphous silicon material.

9. The method of claim 1, wherein the transparent conductive oxide layer comprising zinc oxide is formed by a physical vapor deposition process or an electroless chemical deposition process.

10. The method of claim 1, wherein each of the p-type Si-based layer, the n-type Si-based layer, and the intrinsic Si-based layer independently comprises amorphous silicon.

11. A method for forming a silicon-based photovoltaic device, comprising:
depositing a transparent conductive oxide layer on an underlying surface;
exposing the transparent conductive oxide layer to a very high frequency (VHF) plasma to form a treated surface on the transparent conductive oxide layer during a plasma treatment process, wherein the VHF plasma is generated by ionizing a process gas comprising hydrogen (H₂) and nitrous oxide at an excitation frequency within a range from about 30 MHz to about 300 MHz; and
forming a p-i-n junction over the transparent conductive oxide layer, wherein the p-i-n junction comprises a p-type Si-based layer disposed on the treated surface of the transparent conductive oxide layer.

12. The method of claim 11, wherein the transparent conductive oxide layer comprises a metal oxide selected from the group consisting of zinc oxide, indium oxide, tin oxide, indium tin oxide, cadmium oxide, cadmium stannate, aluminum oxide, doped variants thereof, derivatives thereof, and combinations thereof.

13. The method of claim 12, wherein the transparent conductive oxide layer comprises zinc oxide.

14. The method of claim 11, wherein the excitation frequency is within a range from about 40 MHz to about 150 MHz.

15. The method of claim 14, wherein the transparent conductive oxide layer is exposed to the VHF plasma for a time period within a range from about 2 seconds to about 30 seconds.

16. The method of claim 11, wherein a power level of the VHF plasma is within a range from about 0.1 W/cm² to about 5.0 W/cm².

17. The method of claim 11, wherein the process gas comprises the hydrogen and the nitrous oxide at a H₂/N₂O concentration ratio within a range from about 1:1 to about 10:1.

18. The method of claim 11, wherein the underlying surface is a transparent substrate comprising a material selected from the group consisting of glass, quartz, silicon, silicon oxide, polymeric, oligomeric, and derivatives thereof.

19. The method of claim 11, wherein the p-type Si-based layer comprises amorphous silicon and the p-i-n junction further comprises an intrinsic Si-based layer disposed over the p-type Si-based layer, an n-type Si-based layer disposed over the intrinsic Si-based layer, and each of the intrinsic Si-based layer and the n-type Si-based layer independently comprises amorphous silicon.

20. A method for forming a silicon-based photovoltaic device, comprising:
depositing a first transparent conductive oxide layer comprising zinc oxide on an underlying surface;
exposing the first transparent conductive oxide layer to a very high frequency (VHF) plasma during a first plasma treatment process, wherein the VHF plasma is generated by ionizing a process gas comprising hydrogen (H₂) and nitrous oxide at an excitation frequency within a range from about 30 MHz to about 300 MHz;
forming a first p-i-n junction over the first transparent conductive oxide layer, wherein the first p-i-n junction comprises a first p-type Si-based layer disposed on the first transparent conductive oxide layer;
forming a second transparent conductive oxide layer comprising zinc oxide on a first n-type Si-based layer within the first p-i-n junction;
exposing the second transparent conductive oxide layer to the VHF plasma during a second plasma treatment process; and
forming a second p-i-n junction over the second transparent conductive oxide layer, wherein the second p-i-n junction comprises a second p-type Si-based layer disposed on the second transparent conductive oxide layer.
